(19) United States
(12) Patent Application Publication
(10) Pub. No.: US 2001/0007582 A1
(43) Pub. Date: Jul. 12, 2001

(54) Data transmitting apparatus, automatic level adjustment method and activation control method

(76) Inventors: Takashi Kaku, Kawasaki (JP); Hideo Miyazawa, Kawasaki (JP); Noboru Kawada, Kawasaki (JP); Takeshi Asahina, Kawasaki (JP); Tooru Ogawa, Kawasaki (JP)

Correspondence Address: Helfgott & Karas, P.C., 350 Fifth Avenue, Suite 6024, New York, NY, 10118, US

(21) Appl. No.: 09/789,271

(22) Filed: Feb. 20, 2001

Related U.S. Application Data
(63) Continuation of application No. PCT/JP99/01355, filed on Mar. 18, 1999.

(30) Foreign Application Priority Data
Aug. 21, 1998 (JP) 10-235971

(51) Int. Cl. H03K 9/00; H04L 27/06; H04L 27/14; H04L 27/22

(52) U.S. Cl. 375/316; 375/350

(57) ABSTRACT

A bandpass filter 51 extracts a Nyquist tone signal from an input signal, and a power calculation unit 52 checks the level of the extracted tone signal. A line equalizer control unit 53 controls a line equalizer 42 based on the level of the calculated tone signal. If the level of the tone signal fluctuates beyond a prescribed range, a level adjustment circuit compulsory activation control unit 54 compulsorily activates the line equalizer control unit 53, and if it is judged from the level of the tone signal that the apparatus is in a normal communication state, the level adjustment circuit compulsory activation control unit 54 nullifies the compulsory activation of the line equalizer control unit 53.

### CROSS REFERENCE TO RELATED APPLICATION

This application is a continuation of International PCT Application No. PCT/JP99/01355 filed on Mar. 18, 1999.

### BACKGROUND OF THE INVENTION

1. Field of the Invention

The present invention relates to a data transmitting apparatus. In particular, the present invention relates to a data transmitting apparatus for overlaying on a sending data signal a tone signal having a specific frequency element, extracting the overlaid tone signal at a receiving side device and adjusting the level of the reception signal based on the extracted tone signal.

2. Description of the Related Art

When data are transmitted via a private line, etc., generally a modem is currently used, and a high-speed transmission and inexpensive modem is strongly demanded. In the transmission of image information, a modem with a transmission speed higher than that in ordinary data transmission (e.g. approximately 1.5 Mbps) is demanded, partly because a larger amount of information is transmitted.

Generally, if data are transmitted on a transmission line, such as a metallic line, etc., the characteristic of a transmitted signal changes depending on the characteristic of both a line and a transmission distance.

FIG. 1 shows an example of the frequency characteristic of a metallic line. In the example shown in FIG. 1, a metallic line has a frequency characteristic expressed by the following equation.

$$\frac{1}{\sqrt{f}}$$

Since a metallic line has such a frequency characteristic, an amplitude distortion can occur easily in a transmitted signal and in particular, the high frequency element is easily attenuated than the low frequency element. Such a frequency characteristic varies depending on the line condition (the degree of the amplitude distortion of a reception signal).

The level of a signal transmitted via a line is holistically attenuated. This level fluctuation is chiefly due to a transmission distance, and it has a tendency that the longer a transmission distance, the larger the attenuation degree of the level. Therefore, the attenuation degree of a reception signal level cannot be uniquely defined.

To cope with the amplitude distortion due to these factors of a reception signal, the reception signal has been conventionally equalized using an equalizer. Since, as described above, the amplitude distortion of the reception signal varies depending on a line condition, etc., it is preferable that a signal can be dynamically equalized.

The applicant has proposed a technology for overlaying tone signals each with a specific frequency element, and preferably a plurality of tone signals each with a separated band, distinguishing the characteristics of the respective reception signals based on the levels of these tone signals, performing signal equalization, etc., in Japanese Patent Laid-open No. 9-321672 “Line Equalizer Control Method, Integration Circuit, Frequency Shift Circuit and Transmission Device”. The technology disclosed in the application is briefly described below. For the details, see the application.

FIG. 2 shows the spectrum of the transmission signal of this technology. In FIG. 2, “A” indicates the band of a transmission signal. For example, the transmission band of the application described above is 12 kHz to 204 kHz. In this example, a transmission speed is 1.5 Mbps. “B” and “C” are tone signals which are overlaid on the transmission signal. In the example shown in FIG. 2, in particular, tone signals having a Nyquist frequency are used. Therefore, tone signal B has a single frequency of 12 kHz, and tone signal C has a single frequency of 204 kHz. When being transmitted from a transmitting side device, these tone signals B and C both have respective predetermined levels. In the example of the application described above, the levels of tone signals B and C are the same. If the transmission signals having the spectrum shown in FIG. 2 are transmitted via a line, the characteristics vary depending on the line quality, etc.

FIG. 3 shows an example of a transmission signal spectrum received in a receiving side device. The characteristic of the transmission signal shown in FIG. 3 varies mainly due to two factors. One factor is the frequency characteristic of a line and the other factor is the overall attenuation of a signal level due to a transmission distance, etc. In FIG. 3, as a result of the combination of both the factors, the signal characteristic has been holistically changed. As a result, the levels of tone signals B and C have changed to the levels of tone signals B′ and C′, respectively. In the application described above, the respective reception levels of tone signals B′ and C′ which are overlaid on the transmission signal and are transmitted, are checked and the degree of characteristic change of the reception signal are determined based on the respective reception levels.

Level fluctuations due to the frequency characteristic of a line can be determined by the inclination of a straight line D which connects tone signals B′ and C′, as shown in FIG. 3. If the frequency characteristic of a line is flat, the respective levels of tone signals B′ and C′ become the same as that of the transmitted signal. Therefore, the inclination between both tone signals B′ and C′ is 0. If a high frequency element is more attenuated than a low frequency element, the inclination D goes downward and to the right. Conversely, if a low frequency element is more attenuated than a high frequency element, the inclination D goes downward and to the left.

The overall attenuation degree of a reception signal level can be determined by calculating the average of the levels of tone signals B′ and C′. This average corresponds to an intermediate signal level E of a transmission signal band. Here it is assumed that if attenuation due to the frequency characteristic of a line is not taken into consideration, there is no overall level attenuation. Then, the calculated average level E becomes the same as those of tone signals B and C when a transmission signal is transmitted from a transmitting side device. If a reception signal level is uniformly attenuated over the entire band, the average level E becomes lower than the levels of tone signals B and C when a transmission signal is transmitted from a transmitting side device.

In the technology described above, the characteristic of a reception signal is checked by such a method and the reception signals are equalized by controlling the line equalizer based on the checked reception signal characteristic. In this method, the characteristic of a reception signal is checked only based on the reception levels of tone signals B′ and C′, and the line equalizer is controlled. Therefore, the load of an operation process of checking the reception signal characteristic can be reduced by a fair amount. Training prior to data transmission can also be omitted.

Although in the examples described above, in particular, a tone signal is assumed to be a signal having a Nyquist frequency (Nyquist tone), a tone signal having a band other than a Nyquist frequency can also be overlaid. However, when the inclination between tone signals B′ and C′ or the level of an intermediate band is calculated, the accuracy can be improved if the distance between both tone signals B′ and C′ is long. Therefore, line equalization accuracy can be effectively improved if a Nyquist tone is used. If the line frequency characteristic need not be necessarily taken into consideration, one tone signal is sufficient to check the fluctuation of the receiving level.

FIGS. 4 and 5 show examples of the configurations of a modem used as a data transmitting apparatus to implement the technology described above. FIGS. 4 and 5 show a transmitting side device and a receiving side device, respectively.

In the transmitting side device, sending data (SD) are inputted to a scrambler 1 (SCR) and signals are randomized. Then, a signal point generation unit 2 converts the randomized data into a signal point corresponding to the data value in, for example, units of 8 bits. After the waveform of the generated signal point is reshaped by a roll-off filter (ROF) 3, the Nyquist tone described above is overlaid on the signal point by an addition unit 4. After being modulated by a modulation unit 5, the signal point is transmitted to a line.

In a receiving side device, reception data from the line are first inputted to a line equalizer (LE) 11. The line equalizer 11 equalizes the reception signal level attenuated in the line. The equalized signal is demodulated by a demodulation unit 12 and is inputted to a timing phase control unit 13. The timing phase control unit 13 controls a timing phase to be synchronized with the timing of the opposite station (transmitting side device). The output of the timing phase control unit 13 becomes reception data RD via a roll-off filter (ROF) 14, an equalizer (EQL) 15, a carrier phase control unit (CAPC) 16, a judgment unit 17 and a descrambler (DSCR) 18, and is transmitted to a data terminal, etc.

However, the output of the timing phase control unit 13 is transmitted to a timing extraction unit 19. The timing extraction unit 19 extracts a Nyquist tone element from the received data using a bandpass filter and transmits the extracted Nyquist element to a level adjustment unit 20. The level adjustment unit 20 controls the level in such a way that the level (inclination) of the received Nyquist tone can be maintained constant and generates a control signal for maintaining the level constant. The control signal is transmitted to the line equalizer 11 and controls the line equalizer 11.

However, the technology described above has the following problems.

FIG. 6 shows the spectrum of the output signal of a roll-off filter 3. In FIG. 6, “A” indicates a transmission band. Since in an actual roll-off filter 3, a roll-off ratio cannot be made 0, the vicinity of both ends of the output of the roll-off filter 3 inclines gently.

The transmission data inputted to the roll-off filter 3 are randomized by a scrambler 1. Therefore, in the long term, all band elements are uniformly generated in the spectrum of the output of the roll-off filter 3 and the signal level is comparatively stable, as shown in FIG. 6. Therefore, if a tone signal is overlaid on the output of the roll-off filter 3 shown in FIG. 6 (FIG. 7 shows a state where the output of the roll-off filter 3 is transmitted to a line and bands other than a transmission band are cut), there is a low possibility that the levels of tone signals B and C may be fluctuated, for example, by ±1 dB or more.

However, in the short term, the output spectrum of the roll-off filter 3 changes depending on the pattern of a signal input to the roll-off filter 3. If a tone signal is overlaid on such data, the signal level of a Nyquist frequency band element increases/decreases compared with that shown in FIG. 7.

For example, if an alternating pattern of 1 and 0 is inputted to a roll-off filter, the output has the spectrum shown in FIG. 8. In FIG. 8, the frequency elements B″ and C″ of the sending data (SD) are generated in the position where a tone signal for level judgment is overlaid, and in this example, the frequency element corresponds to a Nyquist tone frequency.

If the tone signals B and C for level judgment described above are overlaid on the sending data (SD) having the spectrum shown in FIG. 8, the level of a Nyquist frequency element extracted as a tone signal increases/decreases as the frequency elements B″ and C″ of the sending data (SD) increases/decreases, as shown in FIG. 9.

In a receiving device, a Nyquist tone frequency element is extracted from a receiving signal as a tone signal and the line equalizer is controlled in such a way that the tone signal level can be maintained constant.

At the time of initial activation, a compulsive activation is performed in such a way that the receiving signal can be rapidly adjusted to within the range of ±1 dB and that the initial activation time can be reduced. Therefore, if the level of a tone signal fluctuates by ±1 dB or more beyond a specific value, the compulsory activation of a level adjustment circuit for adjusting a tone signal level starts operating and thereby there is a possibility that a data error may occur. For example, if the tone signal level increases by 1 dB beyond the specific value, an AGC is operated by the compulsive activation of the level adjustment circuit and the receiving signal level decreases by 1 dB below a normal value and a data error occurs.

However, if a sending data pattern simply changes and data transmission is normally conducted, data transmission itself is normal and there is essentially no need for compulsory activation.

Since the receiving side device does not understand the sending data pattern, the factor of the level fluctuation of the tone signal band element cannot be recognized. Therefore, if the level of the tone signal band element fluctuates beyond the prescribed value, a compulsory activation is always performed.

In this way, if the receiving signal characteristic is attempted to be checked based on the tone signal overlaid on sending data, there is a high possibility that data reception may become unstable, which is a problem.

Therefore, it is an object of the present invention to realize a data transmitting apparatus which can receive stable data by preventing a level adjustment circuit/line equalizer from performing a compulsory activation even if the level of a tone signal generated by a sending data pattern greatly fluctuates.

### SUMMARY OF THE INVENTION

To solve the problems described above, the present invention is configured to judge whether a communication state is normal or abnormal, to perform a compulsory activation only at the time of initial activation and not to perform a compulsory activation at the time of normal operation.

In this way, at the time of the commencement of transmission, the signal level and timing between a transmitting side and a receiving side can be rapidly matched and a communicable state can be quickly obtained, and at the time of normal operation, a compulsory activation can be prevented from being performed by mistake and a data error can be prevented from occurring, even if a receiving signal level fluctuates.

According to one aspect of the present invention, a compulsory activation is configured to be performed only when the level and timing of a receiving signal deviate from the normal states for a specific period.

In this way, if a receiving signal level simply instantaneously fluctuates, a compulsory activation can be prevented from being performed, and if a sending data pattern simply changes and data transmission are normally conducted, a compulsory activation can be prevented frombeing performed by mistake. Therefore, a data error can be prevented from occurring.

### BRIEF DESCRIPTION OF THE DRAWINGS

FIG. 1 shows the frequency characteristic of a metallic line.

FIG. 2 shows the spectrum of a signal on which a tone signal is overlaid.

FIG. 3 shows the spectrum of the signal shown in FIG. 2 which is obtained when the signal is received.

FIG. 4 shows the configuration of a transmitting modem for overlaying a tone signal.

FIG. 5 shows the configuration of the receiving modem for receiving a signal on which a tone signal is overlaid.

FIG. 6 shows the spectrum of the output signal of a roll-off filter.

FIG. 7 shows the spectrum of the signal shown in FIG. 6 on which a tone signal is overlaid.

FIG. 8 shows the spectrum of the output signal of a roll-off filter at the time of a specific pattern transmission.

FIG. 9 shows the spectrum of the signal shown in FIG. 8 on which a tone signal is overlaid.

FIG. 10 shows the configuration of a data receiving side device of one preferred embodiment of the present invention.

FIG. 11 shows the configuration of a modem to which one preferred embodiment of the present invention is applied.

FIG. 12 shows the configuration of the equivalent circuit of a bandpass filter unit.

FIG. 13 shows the configuration of the equivalent circuit of a power calculation unit.

FIGS. 14A through 14C show the spectra of a demodulated signal and a frequency-shifted signal.

FIGS. 15A through 15C show a frequency shift operation.

FIG. 16 shows the configuration of the equalization circuit of an activation control unit.

FIG. 17 shows the configuration of the equalization circuit of a line equalizer control unit.

FIG. 18 shows the operation of an integration circuit.

FIG. 19 shows the configuration of the equivalent circuits of an activation control unit and a line equalizer control unit in which a level range/timing is not checked.

FIG. 20 shows the configuration of a case where the data transmitting apparatus of the present invention is operated by software.

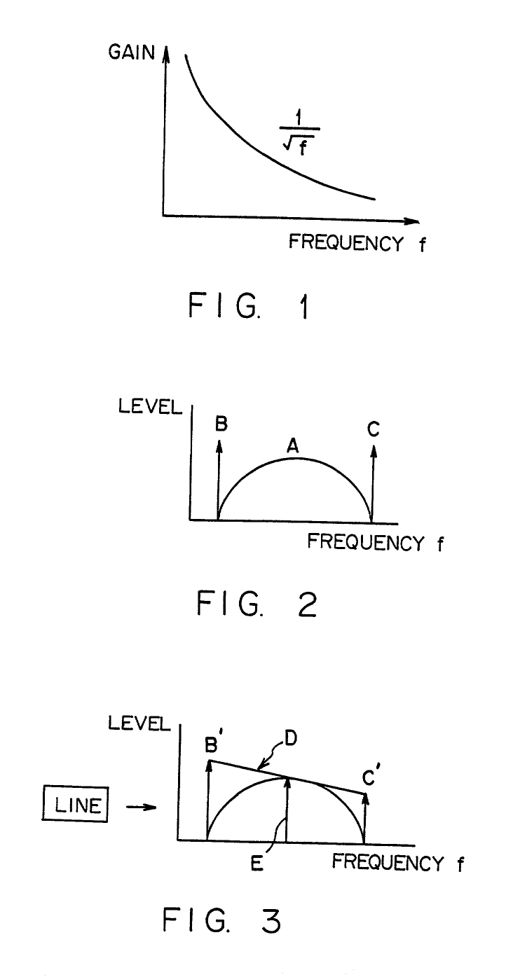

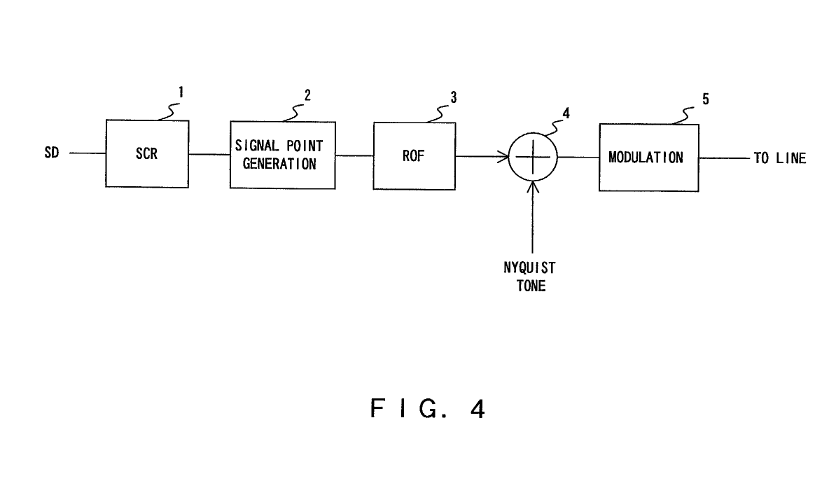

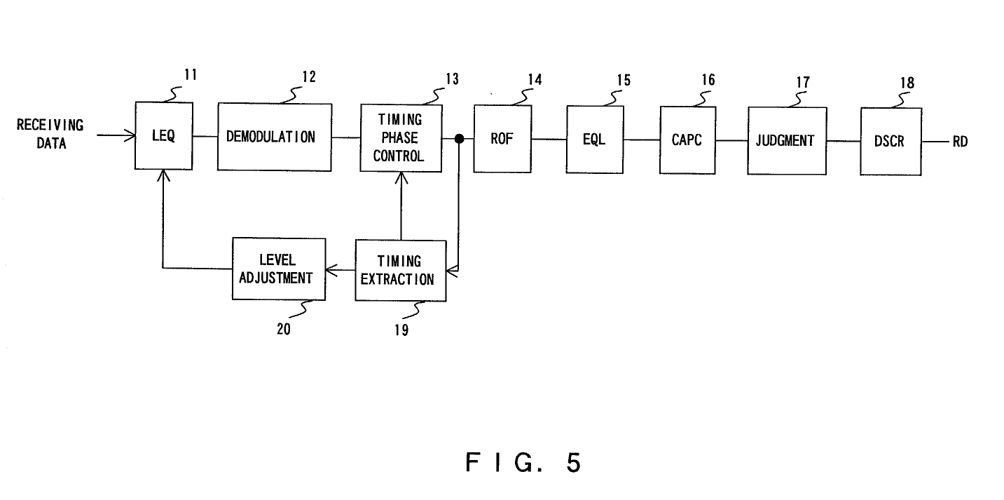

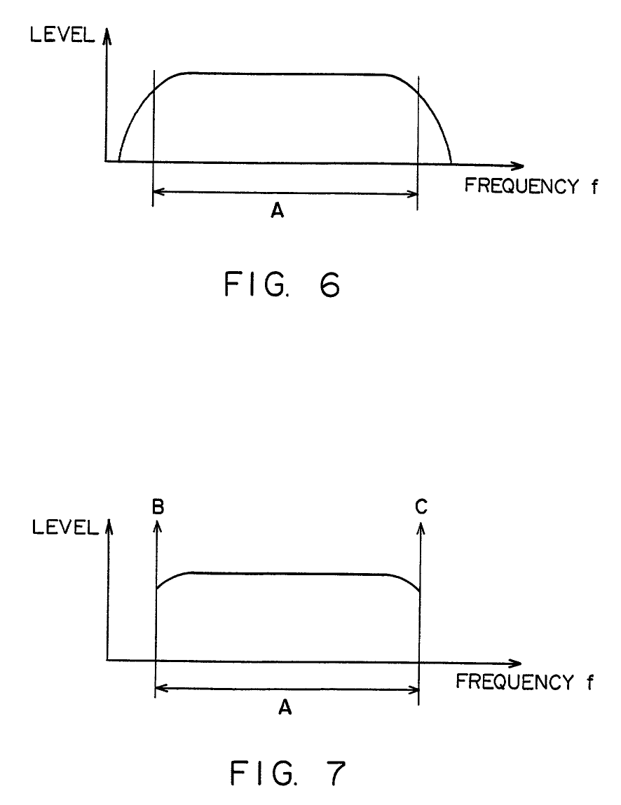

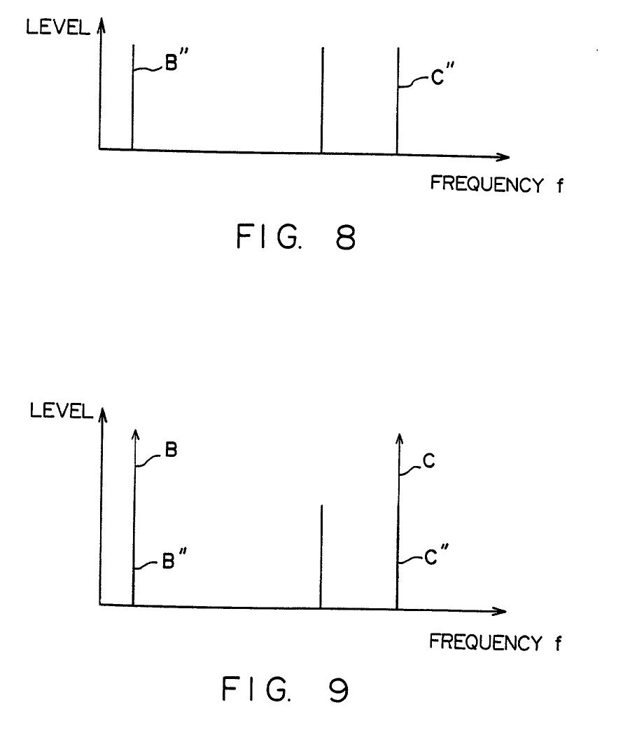

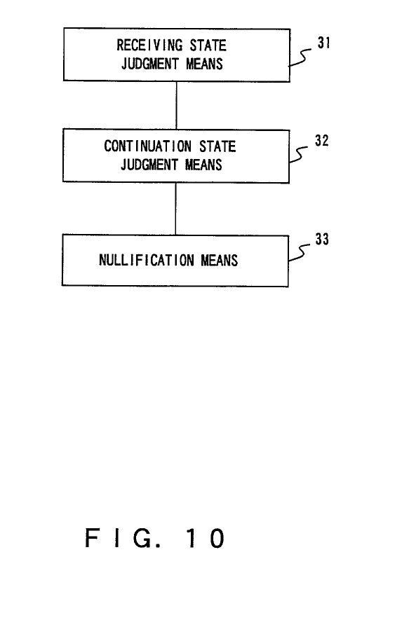

### DESCRIPTION OF THE PREFERRED EMBODIMENTS

The data transmitting apparatus of one preferred embodiment of the present invention is described with reference to the drawings below.

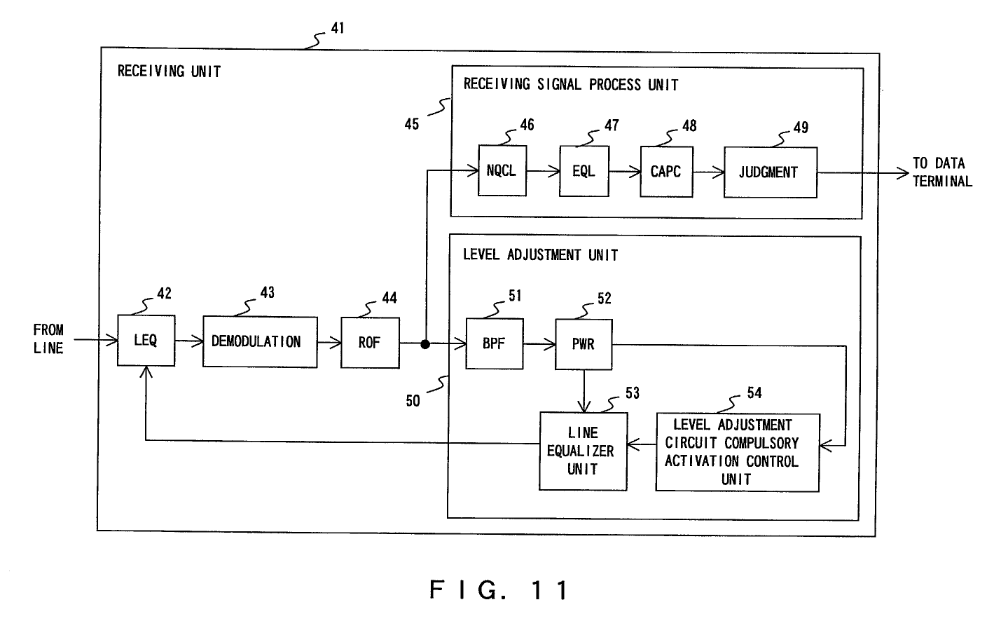

FIG. 10 shows the configuration of a data receiving device of one preferred embodiment of the present invention. In FIG. 10, a receiving state judgment means 31 judges whether the receiving state of a receiving signal is out of a prescribed range and judges whether the receiving state is normal. For example, if a receiving signal level is within ±1 dB of a reference value and the phase is within ±45 degrees, the receiving state can be judged to be normal. A continuation state judgment means 32 checks a time when a receiving signal maintains a prescribed out-of-range state. The continuation state judgment means 32 can be, for example, comprised of an integrator, and the time when the receiving signal maintains the prescribed out-of-range state can be checked by judging whether the accumulation value of the deviation from the prescribed out-of-range state of the receiving signal exceeds a prescribed value. If the time when the prescribed out-of-range state is maintained is within a specific time, a nullifying means 33 treats the receiving state as a normal state, and if the receiving state is normal, the nullifying means 33 nullifies a control to compulsorily adjust the receiving signal level to the reference level.

In this way, if a receiving signal remains in the prescribed out-of-range state for a long time as at the time of the commencement of transmission, both signal level and timing between transmitting and receiving sides can be rapidly matched and a communicable state can be quickly obtained. If the receiving state is normal and a receiving signal level simply instantaneously fluctuates, a compulsory activation can be prevented from being performed. As a result, if a sending data pattern simply changes and data transmission is normally conducted, a compulsory activation can be prevented from being performed by mistake. Therefore, a data error can be prevented from occurring.

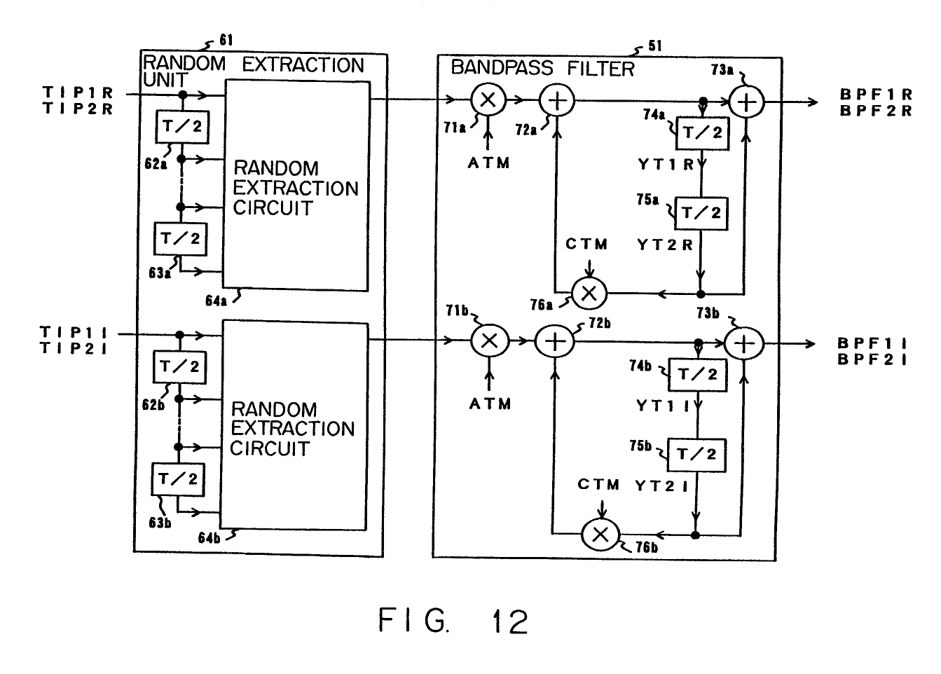

FIG. 11 shows the configuration of the receiving unit 41 of a modem, which is an example of the data transmitting apparatus to which one preferred embodiment of the present invention is applied.

The left end shown in FIG. 11 corresponds to a line side. After the transmission data are equalized or the level is adjusted by a line equalizer 42 (LEQ), sending data inputted from a line is inputted to a demodulation unit 43 and a demodulation process is executed. The demodulated signal is inputted to a roll-off filter 44 (ROF) and the waveform of the receiving signal is reshaped. The output of the roll-off filter 44 is supplied to both a receiving signal process unit 45 and a level adjustment unit 50 for processing receiving data.

The receiving signal process unit 45 executes a signal process to reproduce receiving data. Although the tone signal (Nyquist tone) described earlier is overlaid on the receiving signal, the Nyquist tone is not necessary when the data is reproduced. Therefore, the Nyquist tone is eliminated by a Nyquist signal canceler (NQCL) 46. Then, the receiving signal is equalized by an equalizer (EQL) 47 and a signal point is determined by a judgment unit 49 via a carrier phase control unit (CAPC) 48. The output of the judgment unit 49 is, for example, supplied to a data terminal.

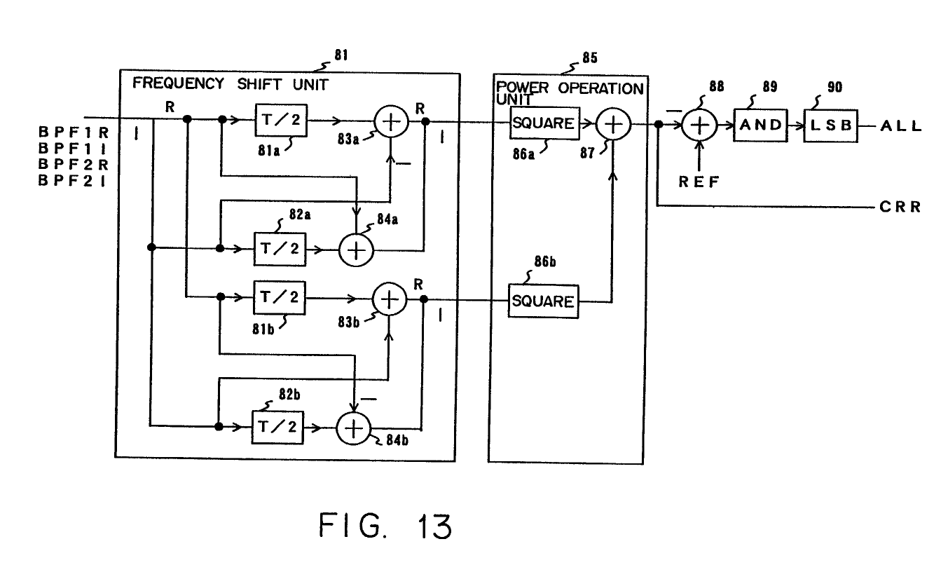

The level adjustment unit 50 directly corresponds to one preferred embodiment of the present invention. The level adjustment unit 50 extracts a Nyquist tone from the receiving data, automatically controls the line equalizer 42 by the level comparison between the extracted Nyquist tone and the reference value REF shown in FIG. 13, levels the frequency characteristic of the receiving signal and adjusts the receiving signal level to a prescribed level.

The level adjustment unit 50 comprises a bandpass filter unit 51 (hereinafter called a “bandpass filter”), a power calculation unit 52, a level adjustment circuit compulsory activation control unit 54 (hereinafter briefly called an “activation control unit”) and a line equalizer control unit 53.

The bandpass filter unit 51 extracts a Nyquist frequency element which is a specific frequency element of a receiving signal. More specifically, the bandpass filter unit 51 comprises a lower group bandpass filter for extracting a lower group Nyquist frequency band and a higher group bandpass filter for extracting a higher group Nyquist frequency band.

The power calculation unit 52 calculates the power (amplitude) of the signal element extracted by the bandpass filter unit 51 and also judges whether a receiving level is adjusted to a prescribed level.

The line equalizer control unit 53 calculates a coefficient used to control the line equalizer 42. The activation control unit 54 monitors the level fluctuation of a receiving signal level based on the output of the power calculation unit 52 and if the fluctuation degree exceeds a prescribed value, the activation control unit 54 instructs the line equalizer control unit 53 to exercise compulsory activation control over the line equalizer 42. The activation control unit 54 also judges whether the modem is currently in a training state or in a normal state, based on the output, timing signal, etc., of the power calculation unit 52, and if the modem is in a normal state, the activation control unit 54 nullifies the compulsory activation described earlier.

In this way, if the tone signal level of the specific frequency band extracted from the receiving signal exceeds a prescribed range, the activation control unit 54 rapidly raises the receiving signal level up to the reference level and quickly obtains a communicable state by compulsorily activating the line equalizer control unit 53. The activation control unit 54 also judges whether the modem is currently normally transmitting/receiving data, and if the modem is in a normal communication state, a compulsory activation is nullified. If the modem is not in a normal data communications state and if, for example, the modem is in a training state, a compulsory activation is validated. Even if a receiving signal level instantaneously fluctuates, a compulsory activation is prevented from being performed by such a control.

Whether the modem is in a normal state can be judged from whether the level of a received signal, in particular, a tone signal of a specific frequency band is within a prescribed range and the nullification/validation is determined by integrating the result. Alternatively, whether the modem is in a normal state can be judged from whether the phase of the timing signal is within a prescribed range and the nullification/validation is determined based on the result. Alternatively, the judgment can be made by combining both the methods.

The operation of this preferred embodiment is further described in detail below with reference to the equivalent circuit of each unit.

FIG. 12 shows the configuration of the equivalent circuit of a bandpass filter unit 51. In the example shown in FIG. 12, a random extraction unit 61 is installed in front of the bandpass filter 51. In FIG. 12, the upper and lower sections correspond to a real element part and an imaginary element part, respectively, and the fundamental configurations are the same. Although both constituent elements are distinguished from each other in FIG. 12 by the last characters “a” and “b” of the reference number, the constituent elements are not provided with the end characters nor distinguished from each other in the following description.

The bandpass filter 51 shown in FIG. 12 is connected to the back of a roll-off filter 44 via the random extraction unit 61, and extracts a plurality of Nyquist frequency signals from a receiving signal. In this way, frequency elements including sending data which are not required to automatically control a line equalizer 42, can be eliminated. Each of four input signals to the bandpass filter 51 is demodulated by a demodulation unit 43 and each input signal becomes a baseband signal. Symbols “R” and “I” attached to each of an input signal and an output signal indicate a real element part and an imaginary element part, respectively.

If a transmitting band is assumed to be 12 to 204 kHz, an input signal to the bandpass filter 51 which is already demodulated, has a band of −96 to +96 kHz. Therefore, the bandpass filter 51 operates to extract both a real element part of the 96 kHz band element and an imaginary element part of the −96 kHz band element. The real element part of 96 kHz band signal and the imaginary element part of 96 kHz band signal correspond to a high-group Nyquist frequency band and a low-group Nyquist frequency band, respectively. Although in the circuit shown in FIG. 12, the upper and lower sections correspond to a part for extracting the real element part and a part for extracting the imaginary element part, respectively, the basic configuration of both the parts are the same.

If the baud rate of a modem is assumed to be, for example, 192 kHz, the line equalizer 42 can be automatically controlled without processing a receiving signal for every baud rate. Therefore, the load of a DPS process can be reduced by dividing a receiving signal into a plurality of sections and processing the divided sections, for example, in units of 12 kHz. If data are processed using only a specific section when amplitude is biased depending on a receiving signal band, the line equalizer 42 cannot be provided with a frequency characteristic corresponding to the character of a receiving signal. Therefore, a random extraction unit 61 is provided in front of the bandpass filter 51 and the overall tendency of a receiving signal can be obtained by randomly extracting a receiving signal in units of 12 kHz.

The random extraction unit 61 comprises multistage-connected taps 62 and 63 and a random extraction circuit 64 for both the real element parts (TIP1R and TIP2R) and imaginary element parts (TIP1I and TIP2I). For the detailed operation of the random extraction unit 61, see the Japanese Patent Laid-open 9-321672 described above, since the operation is not directly related to the operation of the present invention.

The output of the random extraction unit 61 is inputted to the bandpass filter 51. The signal inputted to the bandpass filter 51 is multiplied by a filter coefficient ATM by a multiplier 71. The output of the multiplier 71 is stored in taps 74 and 75 in that order via an adder 72. Each of the taps 74 and 75 is used to store a signal before one timing. The output of the tap 75 is supplied to a multiplier 76, is multiplied by a filter coefficient CTM and is added to the output of the multiplier 76 by the adder 72. The output of the tap 75 is also supplied to an adder 73 and is added to the output of the adder 72. By such a process, signals BPF1 and BPF2 of a band having a Nyquist frequency element are extracted. These signals BPF1 and BPF2 are inputted to the frequency shift unit 81 shown in FIG. 13.

FIG. 13 shows the configuration of a power calculation unit 52. The power calculation unit 52 comprises a frequency shift unit 81 and a power operation unit 85. The frequency shift unit 81 is connected to the back of the bandpass filter 51. The frequency shift unit 81 shifts an input signal +96 kHz/−96 kHz. The frequency shift unit 81 and power operation unit 85 are configured by utilizing the fact that a frequency shift amount of 96 kHz is a half of a Nyquist frequency 192 kHz.

The frequency shift unit 81 receives BPF1R, BPF2R, BPF1I and BPF2I outputted from the bandpass filter 51, and shifts these signals by a prescribed frequency (for example, ±96 kHz) In other words, this frequency shift unit 81 performs the frequency shift of +96 kHz of a Nyquist frequency signal by rotating a signal inputted from the bandpass filter 51 by +96 kHz. In this way, the Nyquist frequency signal can be easily extracted by installing a low-pass filter after the frequency shift.

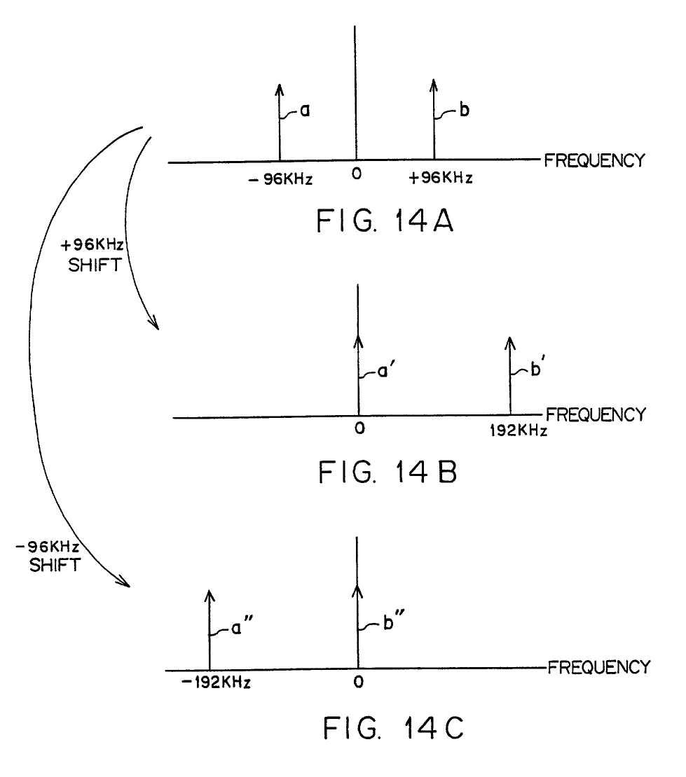

Specifically, out of signals inputted from the bandpass filter 51 to the frequency shift unit 81, a Nyquist frequency element is transmitted, while the sending data frequency element is eliminated. Therefore, the output of the bandpass filter 51 is converted to a baseband signal having a frequency spectrum, as shown in FIG. 14A. As shown in FIG. 14A, each of the frequency elements of Nyquist frequency signals a and b from the bandpass filter 51 is ±96 kHz, and a real element part and an imaginary element part are mixed in the frequency element.

For example, the frequency shift unit 81 divides such a Nyquist frequency element located at ±96 kHz into the element a of +96 kHz and element b of −96 kHz of the Nyquist frequency element by shifting by ±96 kHz, as shown in FIGS. 14B and C. In this way, the extraction of a Nyquist frequency element in the low-pass filter located later can be simplified.

Specifically, the signals a and b which are shown in FIG. 14A can be converted into the element a′ of a frequency of 0 kHz and an element b′ of a frequency of 192 kHz, respectively, by shifting the signals by +96 kHz, as shown in FIG. 14B. However, the signals a and b which are shown in FIG. 14A can be converted into an element a″ of a frequency of −196 kHz and an element b″ of a frequency of 0 kHz, respectively, by shifting the signals by −96 kHz, as shown in FIG. 14C.

In this way, if in the low-pass filter located later, for example, a signal which is shifted by +96 kHz, is inputted, as shown in FIG. 14B, only a signal a′ corresponding to a low-group Nyquist frequency signal is transmitted and the other element b′ corresponding to a high-group Nyquist frequency can be eliminated. In the same way, for example, if a signal which is shifted by −96 kHz is inputted, as shown in FIG. 14C, only a signal b″ corresponding to a high-group Nyquist frequency signal can be transmitted and the other signal a″ corresponding to a low-group Nyquist frequency signal can be eliminated.

In other words, at least one of the Nyquist frequency signals of ±96 kHz can be extracted by shifting a signal from the bandpass filter 51 and passing the signal through a low-pass filter, and thereby there is no need for a process of separating elements of ±96 kHz after passing the signal through a bandpass filter.

If it is assumed that a tone signal of 192 kHz can be represented by a sine wave and that the tone signal of 192 kHz is sampled at a double sampling rate, the two sampling results have the same values with an opposite polarity. Therefore, a low-pass filter can be configured by adding these two sampling results.

If an input signal is assumed to be X+jY, the frequency shift can be expressed by equation (1).

(X+jY)(COS X+j SIN x)=(X COS X−Y SINx)+j(Y COS X+X SINx) (1)

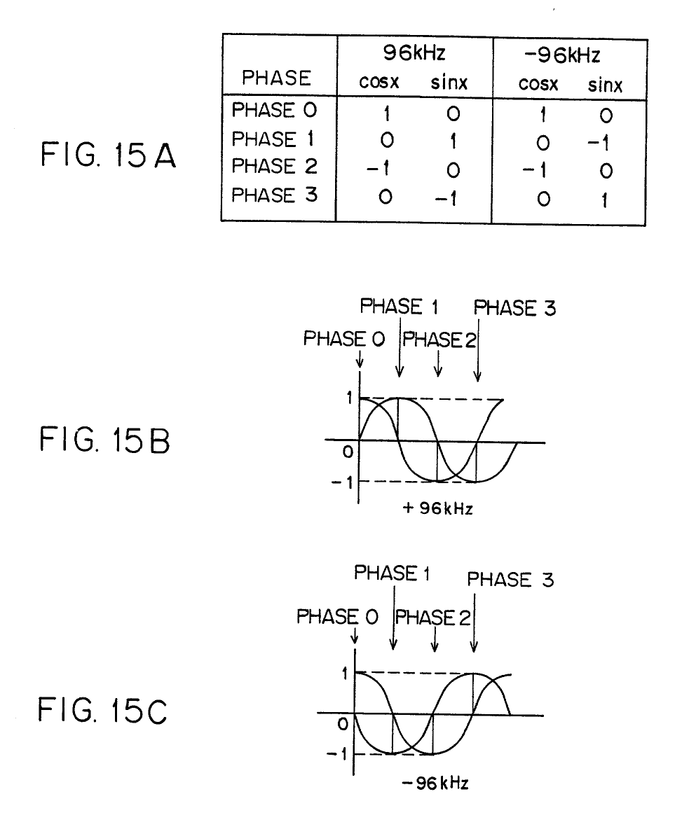

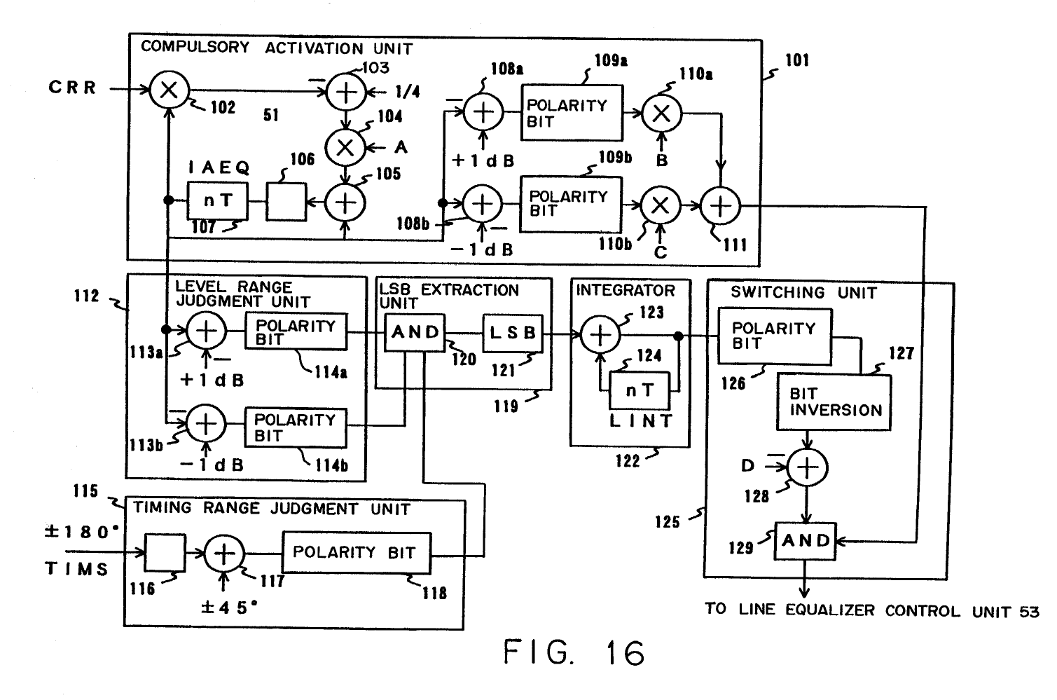

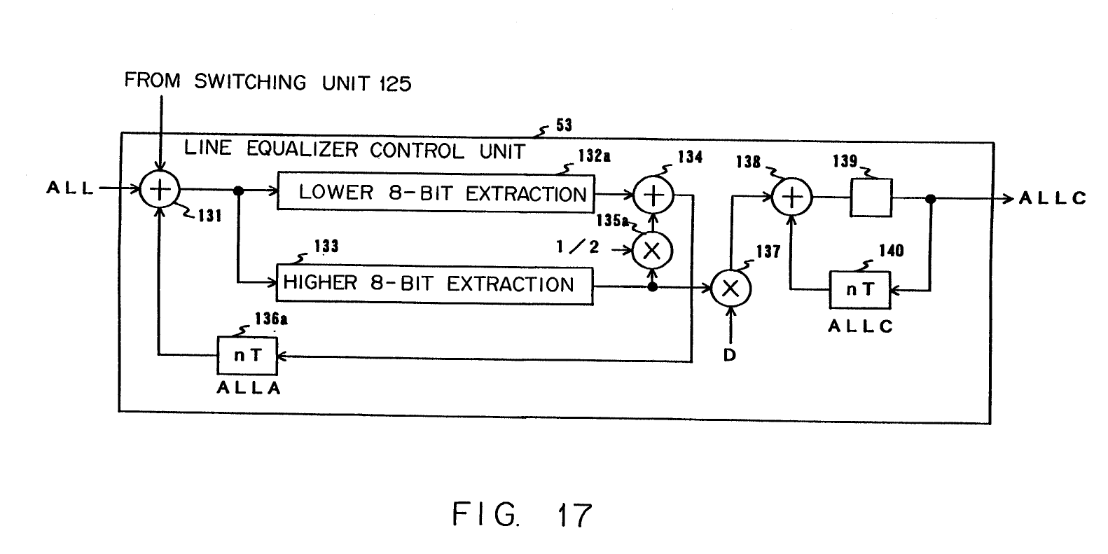

If a sin wave and a cos wave each of which has 96 kHz corresponding to a frequency shift amount, is analyzed into phases 0 to 3 for each increment of π/2, the sin and cos waves for the ±96 kHz shift can be expressed with 0 and ±1, respectively, as shown in FIG. 15A. FIGS. 15B and 15C show the waveforms of +96 kHz and −96 kHz, respectively.

In the case of a +96 kHz shift, each of phases 0 to 3 is calculated according to equation (1) as follows.

Phase 0: X+jY

Phase 1: Y+jX

Phase 2: −X−jY

Phase 3: −Y−jX

In this case, a +96 kHz shift and a low-pass filter can be combined by adding the two phases described above, and the addition results of these two phases are as follows.

Phase0+phase1: (X+Y)+j(Y+X)

Phase1+phase2: (Y−X)+j(X−Y)

Phase2+phase3: (−X−Y)+j(−Y−X)

Phase3+phase0: (−Y+X)+j(−X+Y)

In this case, the phase difference between phase0+phase1 and phase2+phase3 is 180 degrees. In the same way, the phase difference between phase1+phase2 and phase 3 and phase0 is 180 degrees. The phase differences between phase0+phase1 and phase1+phase 2, between phase1+phase2 and phase2+phase3 are all 90 degrees.

In the case of a −96 kHz shift, each of phases 0 to 3 is calculated according to equation (1) as follows.

Phase 0: X+jY

Phase 1: Y−jX

Phase 2: −X−jY

Phase 3: −Y+jX

In this case, a −96 kHz shift and a low-pass filter can be combined by adding the two phases described above, and the addition results of these two phases are as follows.

Phase0+phase1: (X+Y)+j(Y−X)

Phase1+phase2: (Y−X)+j(−X−Y)

Phase2+phase3: (−X−Y)+j(−Y+X)

Phase3+phase0: (−Y+X)+j(X+Y)

The phase relation is the same as that in the case of a +96 kHz shift.

A ±96 kHz shift and a low-pass filter can be combined by configuring the addition results of phase0+phase1, phase1+phase2, phase2+phase3 and phase3+phase0 using a circuit. However, these four addition results have the same power with a different phase. Therefore, it is sufficient to configure one of these four addition results using a circuit. In the frequency shift unit 81 shown in FIG. 13, a ±96 kHz shift and a low-pass filter are combined by focusing on only the relation between phase0 and phase1.

Specifically, the upper section of the frequency shift unit 81, shown in FIG. 13, has both a frequency shift function to perform a +96 kHz shift, and a low-pass filter function, and comprises taps 81a and 82a and adders 83a and 84a. However, the lower section of the frequency shift unit 81, shown in FIG. 13, has both a frequency shift function to perform a −96 kHz shift, and a low-pass filter function, and comprises taps 81b and 82b and adders 83b and 84b. The taps 81a, 82a, 81b and 82b sample an inputted signal of T=192 kHz at a double sampling rate.

In the upper section of the frequency shift unit 81 shown in FIG. 13, a real element part R and an imaginary element part I which are inputted from an input terminal are supplied to the taps 81a and 82a, respectively, and simultaneously supplied to the adders 84a and 83a. The adder 83a calculates the difference between the input real element part at a timing immediately before from the tap 81a and the imaginary element part currently inputted, while the adder 84a adds the input imaginary element part at a timing immediately before from the tap 82a and the real element part currently inputted.

The output of the adder 83a is the real element part of “phase0+phase1”, and the output of the adder 84a is the imaginary element part of “phase0+phase1”.

In the case of the frequency shift unit 81 shown in FIG. 13, both the real element part R and imaginary element part I which are inputted from an input terminal are supplied to taps 81b and 82b, and simultaneously to the adders 84b and 83b, respectively. The adder 83b adds the input real element part at a timing immediately before from the tap 81b and the imaginary element part currently inputted. The adder 84b calculates the difference between the input imaginary element part at a timing immediately before stored in the tap 82b and the real element part currently inputted.

In this way, an equivalent circuit having the configuration of the frequency shift unit 81 functions as both a frequency shift/low-pass filter sharing unit.

A power operation unit 85 is provided after the frequency shift unit 81. In FIG. 13, square circuits are represented by 86a and 86b. The power operation unit 85 converts a vector signal inputted by the square circuit into a scalar signal and outputs the absolute value of the amplitude. Then, the outputs of the square circuits 86a and 86B are added by an adder 87. In this way, the level of a receiving signal is calculated.

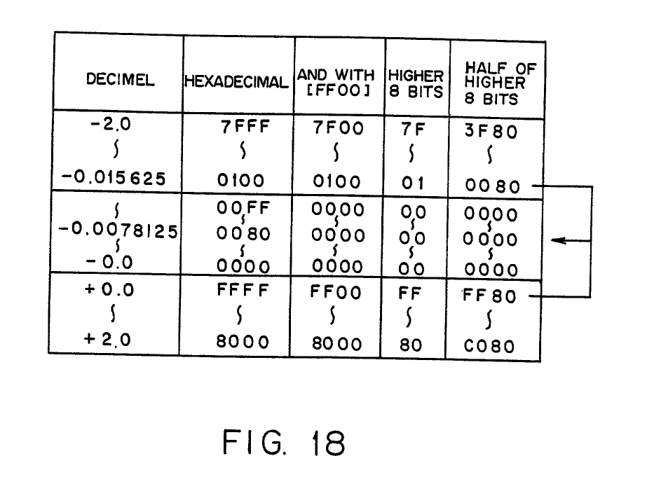

The output of the adder 87 is supplied to the compulsory activation unit 101 shown in FIG. 16 as a signal CRR indicating the amplitude of a tone signal element, and simultaneously is supplied to an adder 88. The adder 88 performs an amplitude error judgment and calculates the difference between a reference value REF and the output of the adder 88. For the reference value, a value which becomes the reference value of a receiving signal level is used, and if the receiving signal level does not reach the reference value, the adder 88 outputs a signal with a negative value.

Then, the output of the adder 88 is supplied to an AND circuit 89. In the AND circuit, the polarity bit of a signal to be inputted is extracted. Then, ±LSB is outputted from an LSB unit 90 according to the polarity of the extracted bit, and this output result is supplied to the line equalizer control unit 53 shown in FIG. 17 as a signal ALL.

FIG. 16 shows the configuration of a level adjustment circuit compulsory activation control unit 54. The level adjustment circuit compulsory activation control unit 54 comprises a compulsory activation unit 101, a level range judgment unit 112, a timing range judgment unit 115, an LSB extraction unit 119, an integrator 123 and a switching unit 125. The level range judgment unit 112, timing range judgment unit 115 and LSB extraction unit 119 judges whether a reception state is normal or abnormal, and the integrator 123 judges whether an abnormal state is instantaneous. The switching unit 125 supplies the line equalizer control unit 53 with an output from the compulsory activation unit 101 only when an abnormal state continues for a specific time, and prevents output from the compulsory activation unit 101 from being supplied to the line equalizer control unit 53 if the reception state is normal or if the abnormal state is instantaneous.

In FIG. 16, a loop between a multiplier 102 and a tap 107 forms an integration circuit, and eliminates noises which are included in a CRR. The input signal CRR to the multiplier 102 normally converges into a specific value. In this example, the value is 0.5. Although the circuit shown in FIG. 16 is comprised of a DSP, the operation range of the DSP is assumed to be +2.0 to −2.0, the value becomes [2000] in hexadecimal notation. A value IAEQ stored in a tap 107 also converges into a specific value, i.e. 0.5, in a normal state. Therefore, in a normal state, the output of the multiplier 102 becomes ¼.

The output of the multiplier 102 is compared with a prescribed constant (¼) by an adder 103. In a normal state, since the output of the multiplier 102 is ¼, the output of the adder 103 becomes 0. However, at the time of activation, since the value of CRR is off from 0.5, the output of the adder 103 takes a value other than 0. Then, after being multiplied by a constant A by a multiplier 104, the output of the adder 103 is inputted to an absolute value calculation circuit 106 via an adder 105. The signal with aphasic absolute value calculated by the absolute value calculation circuit 106 is stored in a tap 107. The output of the tap 107 is added to the output of the multiplier 104 by the adder 105. This output value IAEQ of the tap 107 indicates the fluctuation amplitude of the input signal CRR.

Then, the output value IAEQ of the tap 107 is transmitted to adders 108a and 108b, and is compared with a reference value. As the reference value, a value for judging whether the fluctuation width of a receiving signal exceeds ±1 dB is set and takes values of 0.5±1 dB. In FIG. 16, the values are described as +1 dB and −1 dB for the sake of convenience.

The adder 108a judges whether the input signal fluctuates more than +1 dB. If the input signal fluctuate more than +1 dB, a signal having a negative value is outputted. If the input signal does not fluctuate more than +1 dB, a value having a positive value is outputted.

The adder 108b judges whether the input signal fluctuates more than −1 dB. If the input signal fluctuates more than −1 dB, a signal having a negative value is outputted. If the input signal does not fluctuate more than −1 dB, a signal having a positive value is outputted.

Each of polarity bit generation units 109a and 109b is comprised of an AND circuit and the polarity bit generation units output a polarity bit having a value corresponding to the character of the input signal, which is determined by calculating the logical product of the output of the adder 108a or 108b and the reference value. Specifically, the polarity bit generation unit 109a outputs ‘1’ to a multiplier 110a if the adder 108a outputs a signal having a negative value, and outputs ‘0’ to the multiplier 110a if the adder 108a outputs a signal having a positive value. The polarity bit generation unit 109b outputs ‘1’ to a multiplier 110b if the adder 108b outputs a signal having a negative value, and outputs ‘0’ to the multiplier 110b if the adder 108b outputs a signal having a positive value.

Then, the multiplier 110a multiplies the output of the polarity bit generation unit 109a by a coefficient B. In the same way, the multiplier 110b multiplies the output of the polarity bit generation unit 109b by a coefficient C. As a result, if the outputs of the polarity bit generation units 109a and 109b are both positive, corresponding multipliers 110a and 110b both output 0, and if the outputs of the polarity bit generation units 109a and 109b are both negative, corresponding multipliers 110a and 110b output coefficients B and C, respectively. Then, after being added by an adder 111, the outputs of the multipliers 110a and 110b are inputted to an AND circuit 129 which is described later.

The output of the tap 107 is inputted to a level range judgment unit 112. The level range judgment unit 112 judges whether the level fluctuation width of an input signal is within ±1 dB.

An adder 113a outputs a signal having a negative symbol if the input signal fluctuates less than 1 dB, and it outputs a signal having a positive symbol if it fluctuates more than 1 dB.

An adder 113b outputs a signal having a positive symbol if the input signal fluctuates more than −1 dB, and it outputs a signal having a negative symbol if it fluctuates less than −1 dB.

The outputs of the adders 113a and 113b are supplied to polarity bit generation units 114a and 114b, respectively, and the polarity bit generation units 114a and 114b output polarity bits corresponding to the respective symbols of outputs of the adder 113a and 113b, respectively. Specifically, the polarity bit generation unit 114a outputs ‘1’ to an AND circuit 120 if the adder 113a outputs a signal having a negative value, and outputs ‘0’ to the AND circuit 120 if the adder 113a outputs a signal having a positive value. The polarity bit generation unit 114b outputs ‘1’ to the AND circuit 120 if the adder 113b outputs a signal having a negative value, and outputs ‘0’ to the AND circuit 120 if the adder 113b outputs a signal having a positive value.

A timing signal TIMS has a possibility of fluctuating in the range of +180 degrees. At this time, the timing signal TIMS is inputted to a timing range judgment unit 115 and it is judged whether the phasic fluctuation width of the timing signal is within a prescribed range. In the example shown in FIG. 16, a range of ±45 degrees is set as the normal range of a phasic fluctuation, and if the phasic fluctuation exceeds this range, it is judged that the fluctuation is in an abnormal state.

An absolute value circuit 116 calculates the absolute phasic value of the timing signal TIMS inputted to the timing range judgment unit 115, and an adder 117 judges whether the range of the phasic fluctuation is within ±45 degrees. The adder 117 outputs a signal corresponding to the judgment result. Specifically, if the phasic fluctuation width is within 45 degrees, the adder 117 outputs a signal having a negative symbol and if the fluctuation width is more than 45 degrees, it outputs a signal having a positive symbol. Then, the polarity bit generation unit 118 extracts polarity bits from the output of the adder 117 and the polarity bits are outputted to the AND circuit 120. Specifically, the polarity bit generation unit 118 outputs ‘1’ to the AND circuit 120 if the adder 117 outputs a signal having a negative value, and outputs ‘0’ to the AND circuit 120 if the adder 117 outputs a signal having a positive value.

The outputs of the level range judgment unit 112 and timing range judgment unit 115 are used to judge whether a modem is in a normal state or an actuation state. If the modem is in a normal state, it is considered that both the receiving level of the receiving signal and the phase of the timing signal are stable. However, if the modem is in a training state, both the receiving level and timing are fairly unstable. Therefore, a check of the respective fluctuation width of the receiving level and timing can be performed as a measure to judge whether the modem is in a normal state.

Although in the example shown in FIG. 16, the fact that the receiving level of a receiving signal is within +1 dB of the reference value and the phasic fluctuation width is within ±45 degrees are used for judgment as to whether a modem is in a normal state, other conditions can be also used for the judgment.

The outputs of the level range judgment unit 112 and timing range judgment unit 115 are inputted to the AND circuit 120. If the inputs of the level range judgment unit 112 and timing range judgment unit 115 are both within the respective prescribed ranges, the outputs of the polarity bit generation unit 114a, 114b and 118 are all 1. Therefore, the AND circuit 120 outputs 1. However, either the level or timing is out of the prescribed range or one of the outputs of the polarity bit generation units 114a, 114b and 118 is 0. Therefore, the AND circuit 120 outputs 0.

Then, the output of the AND circuit 120 is inputted to an LSB generation unit 121. In this case, if both the timing and levels are within the respective prescribed ranges, the LSB generation unit 121 outputs −LSB, and if either the timing or level is out of the prescribed range, the LSB generation unit 121 outputs+LSB.

Then, +LSB or −LSB is inputted to an integrator 122 and is integrated. The polarity of a tap value LINT normally becomes negative, and becomes positive at the time of actuation.

Then, a polarity bit is extracted from the output of the integrator 122 by a polarity bit extraction unit 126 and a bit inversion process is performed by a bit inversion unit 127. The difference between the bit-inverted signal and a constant D (for example, [0001]) is calculated by an adder 128. As a result, the adder 128 normally outputs 0 and outputs 1 at the time of actuation. The output of this adder 128 is a signal for instructing the switching between the operation and non-operation of compulsory actuation. A signal which is normally outputted instructs the non-operation and a signal which is outputted at the time of compulsory actuation instructs the operation.

The output of the adder 128 is inputted to the AND circuit 129, and the logical product between the output of the adder 128 and the output of a compulsory activation unit 101 is calculated. Then, the output of the AND circuit 129 is supplied to a line equalizer control unit 53. The AND circuit 129 outputs 0 if the output of the adder 128 is 0, and outputs the outputs B and C of the compulsory activation unit 101 without modification if the output of the adder 128 is 1.

The compulsory activation unit 101 outputs a signal corresponding to the short-term fluctuation of a tone signal, and the output of the adder 128 outputs a signal corresponding to a long-term fluctuation of a tone signal by the function of the integrator 122. Therefore, even if the compulsory activation unit 101 detects the short-term level fluctuation of a tone signal, it can be judged whether the tone signal is stable in the long term by integrating the output values of the level range judgment unit 112 and timing range judgment unit 115. Therefore, even if the level of a tone signal band due to a sending data pattern instantaneously fluctuates, a compulsory activation can be nullified.

FIG. 17 is an equivalent circuit showing the configuration of the line equalizer control unit 53. The output of the compulsory activation unit 101 is inputted to the line equalizer control unit 53 together with a signal ALL. First, ALL is described.

As shown in FIG. 13, ALL is ±LSB. This input value, for example, is 16 bits long. ALL is supplied to both a higher 8-bit extraction unit 133 and a lower 8-bit extraction unit 132 via an adder 131, and the higher 8 bits and lower 8 bits, respectively, of ALL are extracted. The extracted higher 8 bits are reduced by half by a multiplier 135, are added to the lower 8 bits by an adder 134 and are stored to a tap 136 (ALLA). These circuits compose an integration circuit, and ALL, which is to be inputted, is sequentially integrated.

ALL indicates the increase/decrease of a receiving signal level against a reference level. For example, while the receiving signal level is lower than the reference value, +LSB continues to be outputted from an LSB unit 90 as ALL. However, while the receiving signal level is higher than the reference value, −LSB is outputted from the LSB unit 90 as ALL.

It is assumed that each of the higher 8-bit extraction unit 133 and lower 8-bit extraction unit 132 is, for example, comprised of an AND circuit and that ALL is a 16-bit signal as described above, the lower 8 bits can be extracted by performing the AND operation of ALL and [00FF] in hexadecimal notation and the higher 8-bit can be extracted by performing the AND operation of ALL and [FF00].

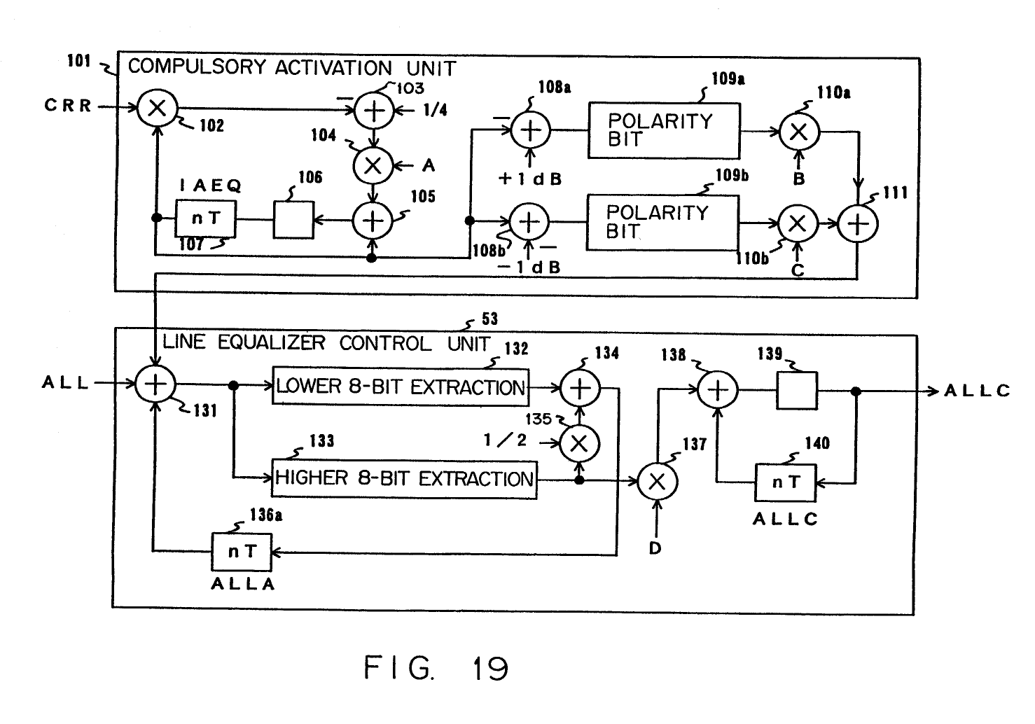

FIG. 18 shows the process of the higher 8-bit extraction unit. Specifically, when the AND operation of the input signal and hexadecimal [FF00] representation is performed by the higher 8-bit extraction unit 133, all the results of the AND operation become [0000] if the input signal is in the range of [0000] to [00FF]. However, if the input signal is in the range of [0100] to [7FFF], the result of the AND operation becomes [0100] to [7F00], and thereby the higher 8 bits of the input signal are extracted.

In the same way, if the input signal is in the range of [FFFF] to [8000], the AND result becomes [FF00] to [8000] and thereby the higher 8 bits are extracted, as shown in FIG. 18 (in the case of FIG. 18, the result is expressed in hexadecimal notation). However, if the AND operation of the input signal and [00FF] is performed by the lower 8-bit extraction unit 132, the AND result becomes [0000] to [00FF] in the range of [0000] to [00FF]. In other words, the same signal as the input signal is outputted. In the range of [0100] to [7FFF], [0000] to [00FF] are sequentially repeated.

However, the multiplier 135 multiplies the output from the higher 8-bit extraction unit 133 by ½, and outputs the half value of the output (higher 8 bits) of the higher 8-bit extraction unit 133.

Specifically, as shown in FIG. 18, if the input signal is in the range of [0000] to [00FF], the higher 8 bits of the AND result is [00], and the output of the multiplier 135 becomes [0000]. However, if the input signal is [0100], the output of the multiplier 135 becomes [0080]. If the input signal is [FFFF], the output of the multiplier 135 becomes [FF80] (the positive/negative-inverted value of [0080]).

Furthermore, an adder 134 adds the output of the lower 8-bit extraction unit 132 (the lower 8 bits of an input signal) and the output of the multiplier 135 (the half of the higher 8 bits of the input signal). As a result, if the input signal is in the range of [0000] to [00FF], the output of the multiplier 135 is [0000]. Therefore, the adder 134 outputs a signal having the same value as the input signal. The output signal from the adder 134 is stored in the tap 136 described earlier as ALLA, and is added to sequentially inputted ALL (±LSB).

However, if the input signal is [0100], the output of the adder 134 becomes [0080], and if the input signal is [FFFF], the output of the adder 134 becomes [0080]. This value [0080] is located precisely at the center of [0000] and [00FF]. In this way, a value [0080] outputted from the adder 134 is stored in the tap 136 as ALLA in the same way as described above.

Since LSB is inputted to the adder 134, the output of the adder 134 fluctuates by approximately ±1LSB at a time. Therefore, the input signal from the adder 134 goes out of the range [0000] to [00FF] ([0100] or [FFFF]), and [0080] is set as ALLA.

Furthermore, the range of [0000] to [00FF] is assigned to determine the adjustment width of the line equalizer 42. If the addition result of the adder 134 exceeds the range described above, the output [0080] from the adder 134 functions to restore the addition result described above so that it is in the middle of this range, and addition can be restarted in the middle.

This range can be properly selected, and can be determined by designating the respective number of higher bits and lower bits. For example, this width can be extended by decreasing the number of the higher bits and conversely can be reduced by increasing the number of the higher bits.

Signals (ALL and DFF) supplied to the integration circuit described above are within ±1, and if there is no activation, an addition value outputted from the adder 131 fluctuates only ±1LSB at a time. Although the output of the integration circuit is used to control a line equalizer 42 located later, by using the smallest possible value, such as ±LSB, the fluctuation of the line equalizer 42 can be suppressed and the operation of the line equalizer 42 can be stabilized.

Signals from the compulsory activation unit 101 are inputted to the adder 131 of a line equalizer control unit 53. If the signal from the compulsory activation unit 101 and ALL are compared, All is ±LSB, while the output of the compulsory activation unit 101 has a larger value than this. For this reason, the value of a signal inputted to the integrator of the line equalizer control unit 53 becomes large, and a period when the addition result of the adder 131 is restored to [0080] is reduced compared with a case where only ALL is inputted. Therefore, if a tone signal suddenly fluctuates, the line equalizer control unit 53 is compulsorily activated by the function of the compulsory activation unit 101.

However, if the judgment results of the level range judgment unit 112 and timing range judgment unit 115 are both within the respective prescribed ranges, the modem is in a normal state. Therefore, the output of the compulsory activation unit 101 described earlier becomes 0. Since in such a case, only ALL is inputted to the line equalizer control unit 53, a period when the addition result of the adder 131 is restored to [0080], becomes long.

The higher 8 bits of the output of the adder 131 are multiplied by a coefficient D by a multiplier 137 and become LSB. Then, an LSB signal is integrated by integrators 138 through 140, and the output ALLC of the integrators 138 through 140 is used as a control signal to control the line equalizer 42.

A system shown in FIG. 19 comprises a compulsory activation unit 101 and a line equalizer control unit 53. The system and the preferred embodiment described above, which is the combination of the systems shown in FIGS. 16 and 17, are compared below. In the case of FIG. 19, neither timing range judgment nor level range judgment are performed, which is not as in the case of FIG. 16. Therefore, in the circuit shown in FIG. 19, if there is the instantaneous level fluctuation of a tone signal, the result is immediately reflected on the line equalizer control unit 53. Therefore, there is a possibility that the compulsory activation of the line equalizer control unit 53 may occur even if there is essentially no need for the compulsory activation of the line equalizer control unit 53 (if there is a level fluctuation of a tone signal, etc., due to the change of a data pattern) and there is a possibility that stable data reception may become difficult.

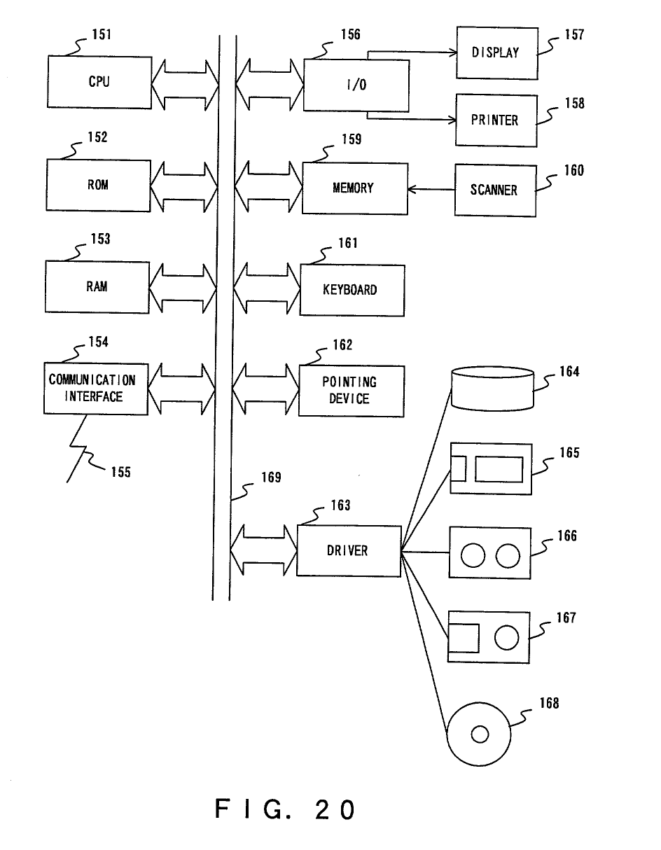

FIG. 20 shows a configuration where the data transmitting apparatus of one preferred embodiment of the present invention is operated by software.

In FIG. 20, a central processing unit (CPU) for performing an overall process, a read-only memory (ROM), a random access memory (RAM), a communication interface, a communication network, an input/output interface, a display for displaying communication data, etc., a printer for printing communication results, etc., a memory for temporarily storing data read by a scanner 160, a scanner for reading communication data, etc., a keyboard, a pointing device, such as a mouse, etc., a driver for driving a storage medium, a hard disk, an IC memory card, a magnetic tape, a floppy disk, an optical disk, such as a CD-ROM, DVD-ROM, etc., and a bus are represented by 151, 152, 153, 154, 155, 156, 157, 158, 159, 160, 161, 162, 163, 164, 165, 166, 167, 168 and 169, respectively.

A communication program and communication data are stored in storage media, such as the hard disk 164, IC memory card 165, magnetic tape 166, floppy disk 167, optical disk 168, etc. Then, a communication process can be performed by reading the communication program and communication data from these storage media to the RAM 153. The communication program can also be stored in the ROM 152.

Furthermore, the communication program and communication data can also be extracted from the communication network 155 via the communication interface 154. For the communications network 155 which can be connected to the communication interface 154, for example, a LAN (local area network), a WAN (wide area network), the Internet, an analog telephone network, a digital telephone network (integrated service digital network (ISDN)), a wireless communication network, such as a PHS (personal handy-phone system), satellite communications, etc., can be used.

When the communication program is started, the CPU 151 extracts a Nyquist tone signal from a receiving signal and checks the level of the extracted tone signal. Then, the CPU 151 exercises the AGC control over the receiving signal based on the level of the extracted tone signal.

The CPU 151 also judges whether the tone signal level fluctuates beyond a prescribed range. If the tone signal level fluctuates beyond the prescribed range, the speed of the AGC control over the receiving signal is increased and the receiving signal level is compulsorily adjusted to the reference level.

In this case, if compulsory activation is performed, it is judged whether the communication state is normal. If the communication state is normal, compulsory activation is prevented from being performed even if the tone signal level fluctuates beyond the prescribed range. In this way, if the level fluctuation of a tone signal is due to the simple change of a data pattern, compulsory activation can be prevented from being performed, and a data error can be prevented from occurring.

In this way, the present invention can be suitably applied to the automatic level adjustment method or compulsory activation control method of a data transmitting apparatus, data receiving apparatus, etc.

What is claimed is:

1. A data transmitting apparatus for receiving a signal obtained by overlaying a tone signal of a specific frequency band element on sending data, extracting the tone signal from a receiving signal and adjusting a level of the receiving signal based on a level of the extracted tone signal, comprising:
means for extracting a signal of a specific frequency band element from receiving data;
means for checking a level of the extracted specific frequency band element signal;
means for comparing the level checked by the judging means with a reference level value;
a level adjustment unit for adjusting the level of the receiving signal based on a comparison of the comparing means;
activation control means for judging whether the level of the specific frequency band element signal fluctuates beyond a predetermined range, and for outputting a signal for instructing an activation of the level adjustment unit if the level fluctuates beyond the prescribed range;
integration means for judging whether the level of the specific frequency band element signal fluctuates within a predetermined range and integrating the result; and
logical product means for outputting a logical product value of an output of the activation control means and an output of the integration means,
wherein validness and invalidness of the activation instruction signal are switched according to an output value of the integration means.

2. The data transmitting apparatus according to claim 1, wherein said integration means
judges whether a phase of a timing signal extracted from the receiving data is within a prescribed range,
comprises a logical product means for calculating a logical product of the judgment result of the timing signal and the judgment result of the specific frequency band element level, and
integrates an output of the logical product means.

3. A data transmitting apparatus, comprising:
extraction means for extracting a specific frequency band element signal from a receiving signal;
calculation means for calculating a level of the extracted specific frequency band element signal; and
judgment means for judging whether the level of the calculated specific frequency band element signal exceeds a reference value; and
integration means for integrating an output of the judgment means,
wherein a normal communication state and an activation state are switched based on the output of the integration means.

4. A data transmitting apparatus, comprising:
extraction means for extracting a specific frequency band element signal from a receiving signal;
calculation means for calculating a level of the extracted specific frequency band element signal;
judgment means for judging whether the level of the calculated specific frequency band element signal exceeds a reference value,
wherein if it is judged from an output of the judgment means that the level of the specific frequency band element signal is within a prescribed range, said data transmitting apparatus judges that the apparatus is in a normal communication state.

5. A data transmitting apparatus, comprising
judgment means for judging whether a phase of a timing signal extracted from a receiving signal is within a prescribed range of a reference value,
wherein if as a judgment result of the judgment means it is judged that the phase of the timing signal is within the prescribed range of the reference value, said data transmitting apparatus judges that the apparatus is a normal communication state.

6. A data transmitting apparatus, comprising:
a line equalizer control unit controlling an operation of a line equalizer for equalizing a receiving signal;
a compulsory activation control unit compulsorily activating the line equalizer control unit for controlling the line equalizer if a level of the receiving signal fluctuates beyond a predetermined range; and
means for judging whether said apparatus is in a normal communication state and nullifying the compulsory activation control of the compulsory activation control unit if it is judged that the apparatus is in a normal communication state.

7. A data receiving apparatus, comprising:
receiving state judgment means for judging whether a receiving state of a receiving signal is out of a prescribed range;
continuation state judgment means for checking a time of maintaining the state where the receiving signal is out of the prescribed range; and
nullification means for nullifying a control to adjust a level of the receiving signal to a reference level.

8. A data transmitting method, comprising the steps of:
overlaying a tone signal for a level check on a transmitting signal and transmitting the signal;
receiving the transmitting signal on which the tone signal is overlaid;
extracting the tone signal from a receiving signal;
generating a first control signal for exercising an AGC control of the receiving signal based on an existence/non-existence of a deviation from a reference level of the tone signal;
generating a second signal for exercising an AGC control of the receiving signal based on an existence/non-existence of a deviation from a prescribed range of the tone signal;
judging whether an receiving state of the receiving signal is normal; and
nullifying the second control signal if the receiving state of the receiving signal is normal.

9. An automatic level adjustment method, comprising the steps of:
receiving a signal;
judging whether a receiving state of the receiving signal is out of a prescribed range;
checking a continuation time of a state where the receiving state of the receiving signal is out of the prescribed range; and
determining to exercise a level control of the receiving signal based on the continuation time.

10. A computer-readable storage medium on which is recorded a program for enabling a computer to execute functions, said functions comprising:
controlling a receiving level of a receiving signal;
compulsorily adjusting the receiving level to a reference level if the level of the receiving signal fluctuates beyond a predetermined range;
judging whether a receiving state of the receiving signal is normal; and
nullifying a compulsory adjustment of the level of the receiving signal.
